(19) United States
(12) Patent Application Publication
(10) Pub. No.: US 2005/0082533 A1
(43) Pub. Date: Apr. 21, 2005

(54) Method of manufacturing transistor, transistor, circuit board, electro-optical device and electronic apparatus

(75) Inventor: Daisuke Abe, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/902,891

(22) Filed: Aug. 2, 2004

(30) Foreign Application Priority Data
Aug. 25, 2003 (JP) 2003-300321(P)

(51) Int. Cl. H01L 29/04

(52) U.S. Cl. 257/72

(57) ABSTRACT

To provide a technology that makes it possible to stably manufacture high-quality transistors, a method of manufacturing a transistor includes forming an interlayer film having a semiconductor film and at least two different films, the interlayer film having a dangling bond in the semiconductor film and/or at a vicinity of an interface of the semiconductor film, forming a backup film that promotes a termination of the dangling bond over the interlayer film and performing a heat treatment after the backup film is formed, subsequent processes after the heat treatment being performed with a temperature lower than 350° C.

### BACKGROUND OF THE INVENTION

1. Field of Invention

The present invention relates to a technology of manufacturing a high-performance transistor at a high yield rate.

2. Description of Related Art

In order to increase the size of an electro-optical device, such as a liquid crystal display device and an organic electro luminescence display device, related art electro-optical devices have employed an inexpensive glass substrate or a plastic substrate as a substrate for the electro-optical device. Since these substrates do not have a high heat resistance, a low temperature process is needed to form a semiconductor device on these substrates. For this reason, a low-temperature polysilicon thin film transistor (TFT), which can be formed at relatively low temperature, has been considered in the related art.

Performance of a transistor is affected by, for example, a structural defect in an interface between a gate insulating film and a semiconductor film. When the low-temperature polysilicon TFT is manufactured by the related art method, it often includes a defect attributable to a dangling-bond, and it is difficult to obtain a fine electrical property.

Under the circumstances, for example, Japanese Unexamined Patent Publication No. 2001-284600 discloses a method that decreases the interface defect. In the method, a gate electrode made of an aluminum-based material is used. Hydrogen is generated at the interface between the gate insulating film and the semiconductor film by performing a heat treatment. By this process, the defect in a semiconductor layer is prevented.

However, this method uses the gate electrode to prevent the defect from occurring, so that choices of a material for the gate electrode are limited. Also, the termination effect of the defect is limited in a certain area.

Japanese Unexamined Patent Publication No. 7-78997 discloses another technology to enhance the performance of a TFT. According to the technology, an interlayer film is formed on a thin film transistor in which a polysilicon semiconductor film is formed as a prevention region. A cap film to reduce or prevent hydrogen from diffusing is formed on the inter-layered film. It can reduce or prevent hydrogen, which is produced by thermolysis of water that is trapped in the interlayer film, from diffusing outside the cap film. In this way, the polysilicon semiconductor film is hydrogenated and it enhances the performance of TFT.

However, even with this technology, the performance of TFT is not yet sufficient level, and it is difficult to stably provide high-quality products with such conventional methods.

### SUMMARY OF THE INVENTION

An exemplary aspect of the invention addresses the above and/or other problems, and provides a technology that makes it possible to stably manufacture high-quality transistors.

In order to address or solve the above problems, a method of manufacturing a transistor of a first exemplary aspect of the present invention includes: forming an interlayer film having a semiconductor film and at least two different films, the interlayer film having a dangling bond in the semiconductor film or/and at a vicinity of an interface of the semiconductor film; forming a backup film that promotes a termination of the dangling bond over the interlayer film; and performing a heat treatment after the backup film is formed, subsequent processes after the heat treatment being performed with a temperature lower than 350° C.

According to the method of the first exemplary aspect of the present invention, after an interface enhancement process in which the heat treatment using the backup film is performed, subsequent processes are performed with a temperature not exceeding a predetermined temperature. In this way, a high performance transistor in which a interface defect is decreased can be stably provided and transistors can be manufactured at a high yield rate.

In this specification, the subsequent processes after the heat treatment include processes through a completion of a final product. Also, the dangling bond refers to a state in which there is an atom that composes the semiconductor film and has an unconnected bond. For example, at an interface between two different semiconductor films, a semiconductor film and a metal film or a semiconductor film and an insulating film. It also refers to an unsaturated bond.

In the method, a metal film or a semiconductor film may be formed as the backup film that promotes the termination of the dangling bond. In this way, defects in the interface can be effectively decreased.

A method of manufacturing a transistor of a second exemplary aspect of the present invention includes: forming a semiconductor film on a substrate; forming an insulating film on the semiconductor film; forming a backup film made of a metal film or a semiconductor film over the insulating film; and performing a heat treatment after the backup film is formed, subsequent processes after the heat treatment being performed with a temperature lower than 350° C.

According to the method of the second exemplary aspect of the present invention, after an interface improvement process in which the heat treatment using the backup film is performed, subsequent processes are performed with a temperature not exceeding a predetermined temperature. In this way, a high performance transistor in which a interface defect is decreased can be stably provided and fine transistors can be manufactured at a high yield rate.

In the method, the heat treatment may be performed with a temperature of 300-450° C., more preferably 350-400° C. With such a temperature range, a state density of an interface is decreased and interface defects and/or a quality of the semiconductor film can be enhanced.

In the method, the metal film or the semiconductor film may be made of Al, Mg, Si, alloys of these elements or an interlayer film that includes a film made of any one of these elements or the alloys at the bottom. In this way, the state density of an interface is decreased and interface defects and/or a quality of the semiconductor film can be enhanced.

In the method, the transistor may be formed to have at least a source electrode, a drain electrode and a gate electrode, and the source electrode or/and the drain electrode is/are formed when the metal film or the semiconductor film is formed. In this way, it is not necessary to newly set up a process of forming a source electrode or a drain electrode. Therefore a high performance transistor can be manufactured at low cost.

In the method, the transistor may be formed to have at least a source electrode, a drain electrode and a gate electrode, and a wiring layer may be formed over the source electrode and the drain electrode when the metal film or the semiconductor film is formed. In this way, it is not necessary to newly set up a process of forming a wiring film. Therefore a high performance transistor can be manufactured at low cost.

A circuit substrate of an exemplary the present invention has a transistor obtained by the above-mentioned method. A high performance circuit substrate can be stably provided since it includes the transistor obtained by the above-mentioned method.

An electro-optical device of an exemplary aspect of the present invention has a transistor obtained by the above-mentioned method. A high performance electro-optical device can be stably provided since it includes the transistor obtained by the above-mentioned method.

An electronic apparatus of an exemplary aspect of the present invention has a transistor obtained by the above-mentioned method. A high performance electronic apparatus can be stably provided since it includes the transistor obtained by the above-mentioned method.

In a method of manufacturing a transistor of an exemplary aspect of the present invention, an interlayer film, having a semiconductor film and at least two different films, is formed. The interlayer film has a dangling bond in the semiconductor film and/or at a vicinity of an interface of the semiconductor film. A backup film that promotes a termination of the dangling bond is formed over the interlayer film. A heat treatment is performed after the backup film is formed. Subsequent processes after the heat treatment is performed with a temperature lower than 350° C.

As examples of the interlayer film that has a dangling bond are, for example, a semiconductor film, an interface between an insulating film and a semiconductor film (silicon), and an interface between a substrate protective film and a semiconductor film (silicon).

The backup film, made of a metal film or a semiconductor film and promoting a termination of the dangling bond, is formed over the interlayer film and then the heat treatment is performed. When subsequent processes after the heat treatment are performed with a temperature not exceeding 350° C., a transistor, in which a quality of the film in an interface and/or crystal nuclei has been enhanced, can be stably obtained.

The action and mechanism of the film quality enhancement is thought to be that dangling bonds, that exist in the interlayer film or in the interface of the interlayer film, are terminated by chemical species, such as hydrogen radical, hydroxy radical, hydrogen ion and hydroxy anion. These chemical species are generated by thermolysis of water that is trapped in the interlayer film.

Specifically, by providing the backup film on the interlayer film that has an interface defect, it becomes possible to contain the generated hydrogen within the backup film. It is thought that because this effectively introduces the hydrogen into the interlayer film, it can promote a termination of the interface defect. Also, it is thought that the termination of the interface defect is driven because a metal film or a semiconductor film used as the backup film promotes a decomposition of water contained in the interlayer film and effectively generates hydrogen.

Further, according to an aspect of the present invention, the backup film is formed, and the subsequent processes after the heat treatment are performed with a temperature not exceeding 350° C. Consequently, hydrogen bonded with the dangling bond is stabilized, and this can preserve an effectiveness of the film quality enhancement.

### BRIEF DESCRIPTION OF THE DRAWINGS

FIGS. 1 (a) through (e) are schematics showing a method of manufacturing a TFT array substrate;

FIGS. 2 (f) through (g) are schematics showing the method of manufacturing the TFT array substrate;

FIGS. 3 (a) through (e) are schematics showing a method of manufacturing an organic EL substrate;

FIG. 4 is a schematic of an organic EL display device;

FIG. 5 is a schematic of a personal computer showing its structures;

FIG. 6 is a schematic of a mobile phone showing its structures;

FIG. 7 is a schematic of a digital still camera showing its structures;

FIG. 8 is a schematic of an electronic book showing its structures as an example of electronic apparatus of the present invention;

FIG. 9 is a graph showing a dependence of a state density of an interface between a gate insulating film and a silicon interface with the temperature of a heat treatment;

FIG. 10 is a graph showing a dependence of the state density of the interface between the gate insulating film and the silicon interface with the temperature of the heat treatment after a treatment of aluminum; and

FIG. 11 is a graph showing a relationship between the state density of the interface between the gate insulating film and the silicon interface and post-processes.

### DETAILED DESCRIPTION OF EXEMPLARY EMBODIMENTS

Exemplary embodiments of the present invention are described below with reference to drawings.

In this exemplary embodiment, a method of manufacturing an organic light-emitting diode (EL) display device is described as an example.

Manufacture of a TFT Array Substrate

Formation of a Semiconductor Thin Film

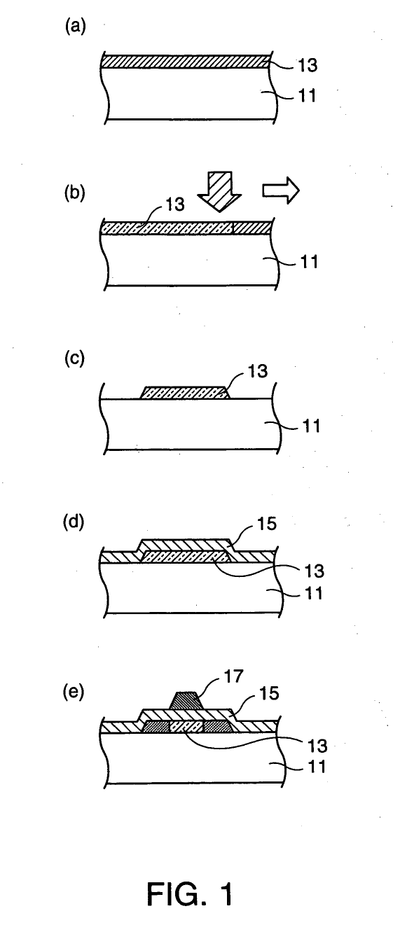

A semiconductor film 13 is formed on a substrate 11 as shown in FIG. 1 (a).

A transparent insulating substrate, such as a quartz substrate, a glass substrate and heat-resistant plastic, is used as the substrate 11.

As the semiconductor film 13, a single elemental semiconductor film of the group IV elements of the periodic table, such as silicon and germanium, a composite elemental semiconductor film of the group IV elements, such as silicon and germanium, a compound semiconductor film of the group III elements, such as gallium and arsenic with the group V elements, and a compound semiconductor film of the group II elements, such as cadmium and selenium with the group VI elements can be used. In addition, N-type semiconductor film to which a donor, such as phosphorous, arsenic and antimony, is introduced, or P-type semiconductor film to which an acceptor, such as boron, aluminum, gallium and indium, is introduced can be also used as the semiconductor film.

These semiconductor films 13 are formed by a Chemical Vapor Deposition (CVD) method, such as Atmospheric Pressure Chemical Vapor Deposition (APCVD), Low Pressure Chemical Vapor Deposition (LPCVD), and Plasma Enhanced Chemical Vapor Deposition (PECVD), or a Physical Vapor Deposition (PVD), such as sputtering and evaporation.

When a silicon film is used as the semiconductor film 13, in the LPCVD method, a temperature of the substrate is approximately 400-700° C. and silicon is deposited using Si₂H₆ and the like. In the PECVD method, a temperature of the substrate is approximately 100-500° C. and silicon is deposited using SiH₄ and the like.

When the silicon film is formed by sputtering, a temperature of the substrate is approximately room temperature to 400° C. As described above, though an initial condition of the semiconductor film 13 in which silicon has deposited can be any state, such as amorphism, mixed crystal, microcrystal and polycrystal. When the semiconductor film 13 is applied to a semiconductor thin film transistor, it is appropriate to set its thickness approximately 20-100 nm.

A substrate protective film (not shown in figures) may be formed between the substrate 11 and the semiconductor film 13. When a semiconductor thin film transistor is formed on a glass substrate, it is important to control a contamination of the semiconductor film 13. Therefore, in order to reduce the likelihood or prevent a movable ion, such as sodium ion, in the glass substrate 11 from being mixed into the semiconductor film 13, the semiconductor film 13 may be deposited after the substrate protective film is formed. An insulative material, such as an oxide silicon film and a silicon nitride film, is used as the substrate protective film.

Crystallization of the Semiconductor Thin Film

Next, the deposited semiconductor film 13 is crystallized as shown in FIG. 1 (b). Here, “crystallization” means that an amorphous semiconductor film is transformed into a polycrystalline or single-crystal semiconductor film by heat energy. Further, the crystallization also enhances that heat energy is given to a microcrystalline or polycrystalline semiconductor film and it improves their crystal film quality or it recrystallizes them by vitrification. In this specification, “crystallization” includes not only crystallization of amorphism but also includes crystallization of polycrystal or microcrystal.

The semiconductor film 13 can be crystallized by laser irradiation or solid phase crystallization. However, the semiconductor film 13 may be crystallized through other measures.

As an example of methods of forming polysilicon TFT, a method of crystallization with laser irradiation, which can be performed at low temperature process, is described.

The substrate on which the semiconductor film 13 is formed is set in a chamber for laser irradiation. The chamber is not shown in figures. The inside of the chamber is in vacuum or filled with non-acid gas atmosphere, and the semiconductor film is irradiated with a laser in the chamber. This laser light may be strongly absorbed in a surface of the semiconductor film 13, but it should be hardly absorbed in the substrate protective film or the substrate 11. A laser may be used that can emit a light whose wave length is in an ultraviolet range or near ultraviolet, such as an excimer laser, an argon ion laser and a harmonic yttrium aluminum garnet (YAG) laser. In order to reduce the likelihood or prevent the substrate 11 and the semiconductor film 13 from being damaged, it is necessary that the laser should be a pulse oscillator that can generate the pulse with large power over a very short period of time. Among above-mentioned lasers, especially the excimer laser, such as a xenon chloride (XeCl) laser (wavelength: 308 nm) and a krypton fluoride (KrF) laser (wavelength: 248 nm), are most appropriate.

A method of irradiating the laser light will now be explained. A half power width of the laser pulse is set at a short time or approximately 10-500 ns. The laser irradiation is performed when a temperature of the substrate 11 is approximately between room temperature (25° C.) and 400° C. An irradiated area of the laser in a single irradiation is diagonally approximately 5-60 mm² and a shape of the area is a square or a rectangle.

As an example, a case of using a beam that can crystallize about 8 mm² square area in a single laser irradiation is explained. After a single laser irradiation to a place, the substrate and the laser are relatively displaced with a little distance in a horizontal direction. Then, another laser irradiation is performed. This step can be applied to a large substrate by continuously repeating this shot and scan process. Specifically, the shot is repeated as a target area is displaced from 1% to 99% at each irradiation.

First, a scan is performed in the horizontal direction (X-direction). Second, they are slightly displaced in a vertical direction (Y-direction) and then the shot and scan process is continuously carried out as they are displaced again with a certain distance in the horizontal direction. Afterward, above-described steps are repeated and the whole surface of the substrate is irradiated. It is a first time irradiation.

In a case of the xenon chloride laser, its laser irradiation energy density of the first time irradiation may be between 50 mJ/cm² and 600 mJ/cm². If it is necessary, radiation is performed a second time to the whole surface of the substrate after the first irradiation.

When the second irradiation is performed, its energy density may be higher that that of the first irradiation, specifically, it may be between 100 mJ/cm² and 1000 mJ/cm². A way of scanning is the same as that of the first time irradiation. The scan is carried out as a square irradiation area is displaced with a predetermined distance in Y-direction and X-direction.

Further, it is possible to perform a third or fourth time irradiation in which the energy density is much higher. With this multiple-step laser irradiation, unevenness due to an edge of the laser irradiation area can completely disappear.

Not only in each step of the multiple-step laser irradiation, but also in the normal single irradiation, every irradiation is conducted with about 5% less energy than an energy density with which the semiconductor film 13 melts completely. Once the silicon film is completely melted, a liquid silicon film will go into a super-cooled state. As a result, crystal nuclei are generated in a high density. A polysilicon film formed by such developing process will become a so called microcrystal in which microcrystal grains exist in a high density. Since such a polysilicon film has many crystal grain boundaries, many defects (mainly a dangling bond) exist in the film and it is unable to be used as a TFT.

Although the method of laser crystallization using a square laser beam was described above, the laser irradiation area may be a form of line whose width is more than about 100 μm and whose length is more than several tens centimeter. The crystallization can be performed by scanning with this line-formed beam light. In this case, a beam overlap in a beam width direction at each irradiation is approximately 5-95% of the beam width. If the beam width is 100 μm and the beam overlap is 90%, the beam moves 100 μm at each irradiation. It means that one point receives 10 times of laser irradiation.

Generally, the laser irradiation may be performed more than 5 times so as to crystallize the semiconductor film throughout the substrate. This means the beam overlap at each irradiation should be more than 80% of the beam width. To securely obtain a highly crystallized polycrystalline film, the beam overlap may be set to be about 90-97% so that one point is irradiated about 10 to 30 times. With the linear beam, a large area can be crystallized by scanning in one direction, so it has an advantage that a throughput will be enhanced compared to a case of the square beam.

Also, an activation rate of impurities introduced into the semiconductor film can be enhanced by repeating the irradiation many times. A condition of the highest irradiation energy density is the same as the one mentioned above.

Isolation Process

Next, an isolation process to delimit a region of the TFT is carried out as shown in FIG. 1 (c). Though a local oxidation of silicon (LOCOS) method, a field shield method or shallow trench isolation (STI) method can be used as an isolation scheme, here, an isolation method of photolithography and etching, which is commonly used in a manufacturing process of TFT, is described.

A mask pattern made of photoresist is formed by photolithography such that only a part that is going to be an active layer of the transistor remains. The semiconductor film 13 is wet etched or dry etched using this resist as the mask. Then, the photoresist is detached.

Formation of a Gate Insulating Film

Next, after the formation of the semiconductor film 13, an insulating film 15 is formed on the semiconductor film 13, as a gate insulating layer of the TFT, as shown in FIG. 1 (d).

As a method of forming the insulating film 15, such chemical vapor deposition (CVD) method as atmospheric pressure chemical vapor deposition (APCVD), low pressure chemical vapor deposition (LPCVD) and plasma enhanced chemical vapor deposition (PECVD) or sputtering can be used.

In this exemplary embodiment of the present invention, an oxide silicon (SiO₂) film is turned into the insulating film 15 especially by parallel plate type radio frequency (RF) plasma CVD using tetraethyl orthosilicate (TEOS).

In this case, though gases used in a vacuum plasma room are the TEOS (Si [OC₂H₅]₄) and oxygen gas (O₂), noble gases, such as helium (He) and argon (Ar) may be mixed in them. A degree of vacuum at the time of the film forming is approximately 100-200 Pa, and the temperature of the substrate at the time of the film forming may be about 300-400° C. By forming the film under these condition, the high quality oxide silicon film 15 (the gate insulating film) that has a high insulation performance and a low electric charge density can be obtained.

Formation of a Gate Wiring

A gate wiring 17 is formed on the oxide silicon film 15 (the gate insulating film) as shown in FIG. 1 (e).

First, a gate wiring film is formed on the oxide silicon film 15.

To form the gate wiring film, metals, such as tantalum, aluminum, and titanium, nitride metals or polysilicon may be deposited or deposited by an appropriate method, such as spattering, a CVD method and a deposition method.

Next, the gate wiring film is patterned and the gate wiring 17 is formed.

Implantation of Impurities and Activation Process

Following the formation of the gate wiring, a source drain region is formed in the semiconductor film 13 by impurity ion implantation. The gate wiring 17 serves as a mask for the ion implantation so that a channel is only formed under a gate electrode. It is a so called self-aligning structure. An ion doping method or an ion implantation method can be applied to the impurity ion implantation. In the ion doping method, a non mass separator type ion implanter is used to implant dopants, which are hydride and hydrogen. In the ion implantation method, a mass separator type ion implanter is used to selectively implant intended impurities. As a material gas for the ion doping method, hydride of impurity's element, such as phosphine (PH₃) and diborane (B₂H₆) that are diluted with hydrogen in about 0.1-10% concentration are used. In either the ion doping method or the ion implantation method, the temperature of the substrate at the time of the ion implantation may be less than 350° C. in order to keep the gate insulating film stable. When a complementary metal-oxide semiconductor (CMOS) TFT is formed, an appropriate mask member made of polyimide resin and the like is used to alternately cover an N-channel metal oxide semiconductor (NMOS) and a P-channel metal oxide semiconductor (PMOS), and the ion implantation is performed in the above-described way.

Then, activation of the impurities is performed. As a method of the activation, there are a laser irradiation method, a low temperature heat treatment method using a furnace whose temperature is more than 300° C. and a rapid thermal processing method with a lamp. An appropriate one for the activation can be chosen out of these methods.

Formation Process of an Interlayer Insulating Film

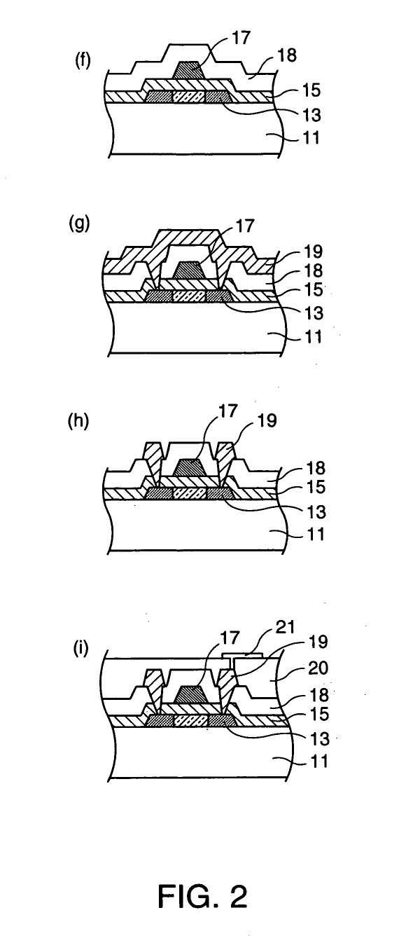

Next, an interlayer insulating film 18 is formed by accumulating oxide silicon on the substrate 11 by a CVD method and the like, as shown in FIG. 2 (f).

Formation of a Metal Layer as a Backup Film and a Thermal Process

Next, a contact hole is formed on a region corresponding to a source-drain region of the gate insulating film 15. Then, a metal film 19 as a backup film is deposited on the gate insulating film 15 in which the contact hole is formed. As a material for the metal film 19, for examples aluminum (Al), magnesium (Mg), alloy of aluminum and magnesium, alloy includes aluminum or magnesium, nitride of aluminum or magnesium and oxide of aluminum or magnesium can be used. With this metal film 19, it is possible to decrease a level of interface between the semiconductor film and the oxide silicon film or in the oxide silicon film. As a reason for the decrease of the level of interface, it is thought that dangling bonds that exist in the film or in the film interface are terminated by chemical species, such as hydrogen radical, hydroxy radical, hydrogen ion and hydroxy anion. These chemical species are thought to be generated by catalytic action of the metal film 19.

To form the metal film 19, any method, such as sputtering, vapor deposition, and CVD can be applied. However, the sputtering is favorable to deposit the metal in a large area. As mentioned above, a relatively active metal, such as aluminum and magnesium, may be used as the metal. For example, compared to a case in which a chemically stable metal, such as gold and platinum is deposited, an effect in enhancement of the gate insulating film 15 is clearly seen when the active metal is deposited. It is undesirable to use an alkaline metal and the like, which moves in the oxide silicon film 15 and serves as so called a movable ion. When the alkaline metal is used as the above-mentioned metal, it deteriorates a quality of the insulating film.

After such an appropriate metal film 19 is deposited, a heat treatment with a temperature more than 300° C. is performed for more than 10 minutes. Any atmosphere can be used for the heat treatment. By performing the heat treatment, the state density of the interface between the semiconductor film 13 and the oxide silicon film 15 is lowered to maintain a fine insulation performance and a fine characteristic of charge density in the oxide silicon film 15.

Conditions for the heat treatment are not limited to the above-mentioned one. A temperature of the heat treatment may be 300-450° C., preferably, 350-400° C. A treating time of the heat treatment may be, for example, more than 30 minutes, preferably, 30-60 minutes.

Further, instead of the metal film, a semiconductor film can be used as the backup film. As the semiconductor film material, for example, silicon (Si) is preferably used because it can decrease the state density of the interface. In this case, its action and mechanism will be the same as those of the metal film.

In the present invention, it is important to perform the rest of processes within a temperature range that does not exceed 350° C.

Patterning of a Source Electrode and a Drain Electrode

Next, a source and drain electrodes and a wiring 16 are formed by patterning the metal film 16 as shown in FIG. 2 (h).

Formation of a Protection Film and a Picture Electrode

Following the patterning, a protection film 20 is formed on them by accumulating oxide silicon, nitride silicon, phosphosilicate glass (PSG) and the like. Then, a through-hole is formed in the protection film 20, and then a picture electrode is formed by sputtering metal, such as indium tin oxide (ITO) and the like.

Finally, in this way, a TFT array substrate is obtained.

Manufacture of an Organic EL Substrate

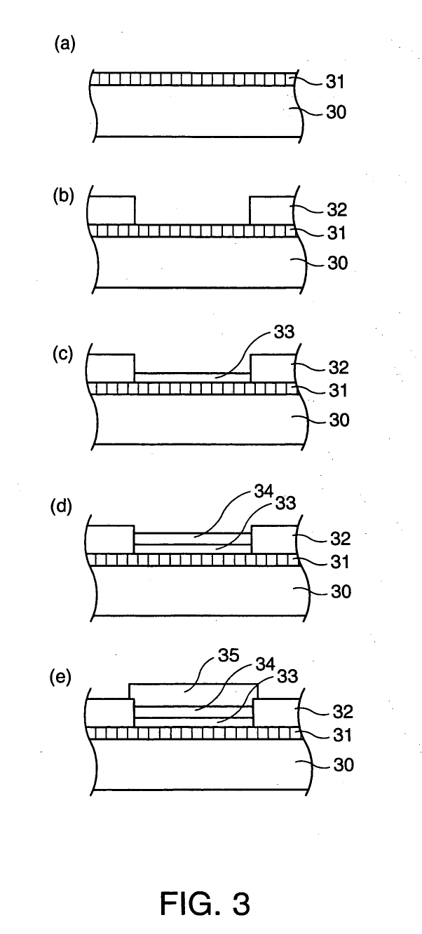

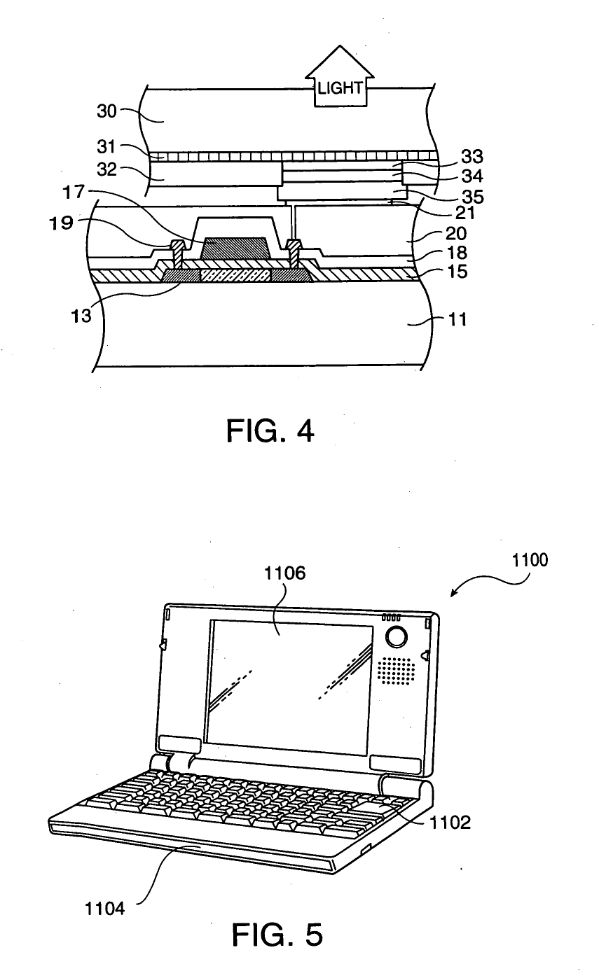

An organic light-emitting diode (EL) substrate on which organic EL is formed, is formed in other processes as shown in FIGS. 3(a)-3(e).

First, a transparent electrode layer 31 is formed on a whole surface of a substrate 30 made of glass and the like by sputtering ITO and the like. See FIG. 3 (a).

Second, an insulating film made of nitride silicon and the like is formed on the transparent electrode layer 31. Then, a bank 32 made of the insulating film is formed by removing a part of the insulating film which corresponds to a picture region by etching and the like. See FIG. 3 (b).

On a part of the transparent electrode layer 31, which is separated by the bank 32 and corresponds to a pixel formed region, an electron hole injection layer 33 is formed by deposition and the like (FIG. 3 (c)). A material that can be injected as an electron hole into a luminous layer in consideration of the luminous layer and a positive electrode, such as NPD, triphenylamine derivative, porphin compound, polyaniline, its derivatives, polythiophene, its derivatives and the like can be used as the electron hole injection layer 33.

Further, an organic EL layer 34 is formed on the electron hole injection layer 33 by deposition (see FIG. 3 (d)).

A metal complex, such as a metal complex of quinoline and the like, a metal complex of azomethine group, a conjugated low molecule and a conjugated macro molecule can be used as the organic EL material. A method of forming the EL layer is not limited to the deposition but it can be formed by applying a solvent of the organic EL material.

Further, a negative electrode layer 35 is formed on the organic EL layer 34 by depositing aluminum, lithium, magnesium, calcium, alloys of these metals, halogenide and the like. And then, an organic EL substrate is obtained. See FIG. 3 (e).

Joining the TFT Array Substrate and the Organic EL Substrate

The TFT array substrate and the organic EL substrate formed in the above-described way are bonded together such that the picture electrode 21 of the TFT array substrate contacts with the negative electrode layer 35 of the organic EL substrate. In this way, an organic EL display device is formed.

A commonly used anisotropic conductive paste or an anisotropic conductive film can be used to bond the TFT array substrate and the organic EL substrate.

To explain this exemplary embodiment of the present invention, though the processes are in the above-described order, the order is not limited to this and can be changed. For example, the isolation process may be performed after the gate insulating film 15 is formed. Also, the impurities implantation process using the resist mask or other metal masks may be performed before the gate insulating film 15 is formed.

A film enhancement process by a plasma treatment and the like may be performed immediately after the gate insulating film 15 is formed or the crystallization process.

In this exemplary embodiment, though the formation process of the backup film is conducted after the interlayer insulating film 18 is formed, the order is not limited to this. For example, the formation process of the backup film may be conducted after the protection film 20 is formed. In this case, the backup film can be used as the picture electrode. Also, the backup film may be formed before the interlayer insulating film 18 is formed. In this case, subsequent processes need to be performed with a temperature not exceeding 350° C.

In this exemplary embodiment, though the organic EL substrate and the TFT array substrate are separately manufactured in the different processes, they can be manufactured in the same process by, for example, forming the organic EL layer and others on the transistors. In this case, related art methods are appropriately selected and manufacturing processes are performed with a temperature not exceeding 350° C.

The present invention is not limited to the above-described exemplary embodiments but may be applied to various kinds of modifications within the scope and spirit of the present invention.

The transistors manufactured by the manufacturing process of an exemplary aspect of the present invention may be used in the organic EL display device or a liquid crystal display device that has a large glass substrate and requires manufacturing through low temperature processes. Examples of electronic apparatus including such display device are described below. However, applications of the present invention are not limited to the examples.

Mobile Computer

An example of which the display device including the transistor according to the above-described exemplary embodiment of the present invention is applied to a mobile personal computer (information-processing device) is explained. FIG. 5 is a schematic of a personal computer showing its structures. The personal computer 1100 is composed of a main body part 1104 having a keyboard 1102 and a display device unit having the above-mentioned display device 1106 as shown in the figure.

Mobile Phone

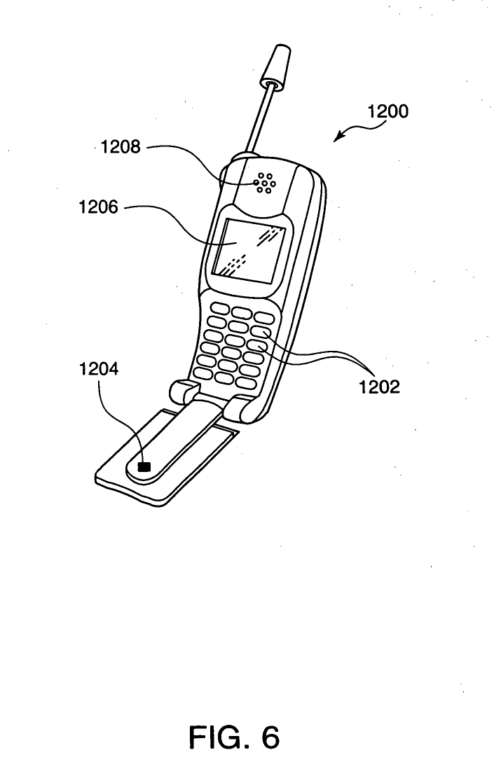

An example of which the display device according to the above-described exemplary embodiment is applied to a display part of a mobile phone is explained. FIG. 6 is a schematic of the mobile phone showing its structures. The mobile phone 1200 includes a plurality of manual operation buttons 1202, an ear piece 1204, a mouth piece 1206 and the display device 1208 as shown in the figure.

Digital Still Camera

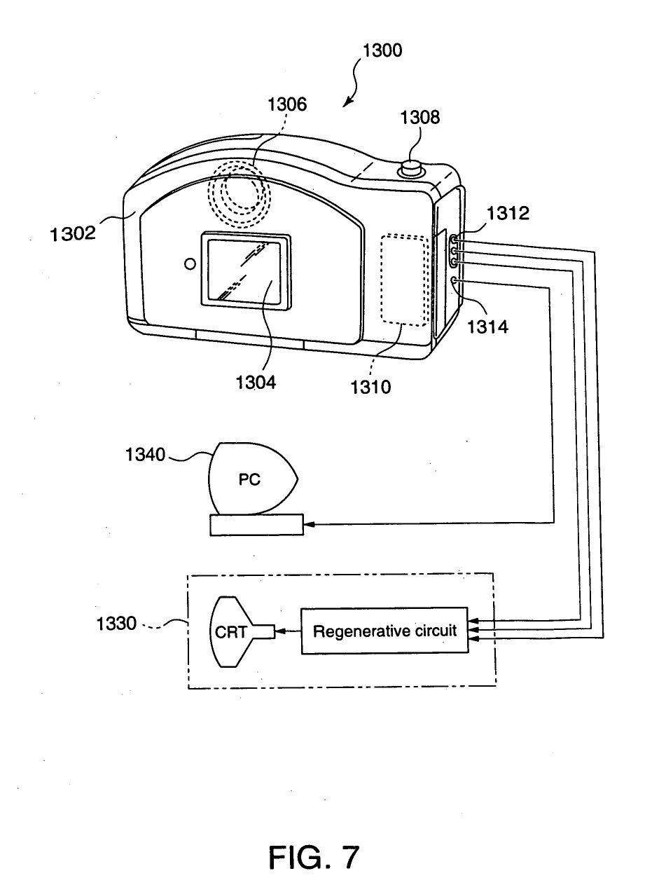

An example of which the display device according to the above-described exemplary embodiment is applied to a finder of a digital still camera is explained. FIG. 7 is a schematic of the digital still camera showing its structures as well as schematically showing its interfaces to external devices.

A normal camera exposes a film to a subject light image. In a digital still camera 1300, an image signal is generated by an imaging element, such as a charge couple device (CCD), that transforms the subject light image from photo to electric. The above-mentioned display device 1304 is installed behind a case 1302 of the digital still camera 1300, and it displays according to the image signal from CCD. For this reason, the display device 1304 serves as the finder that displays the subject image. Also, a photo acceptance unit including an optic lens, CCD and the like is installed in a viewing screen side (in the figure, a back side) of the case 1302.

When a photographer sees a subject image displayed on the display device 1304 and presses a shutter button 1308, an image signal of CCD at the time is transferred and stored in a memory of a circuit substrate 1310. This digital still camera 1300 has a video signal output terminal 1312 and an input-output terminal 1314 for data communication on a side surface of the case 1302. A television monitor 1330 is plugged in the video signal output terminal 1312 and a personal computer 1340 is plugged in the input-output terminal 1314 as shown in the figure, according to need. Further, the image signal stored in the memory of the circuit substrate 1310 is output to the television monitor 1330 and the computer 1340 with a predetermined operation.

Electronic Book

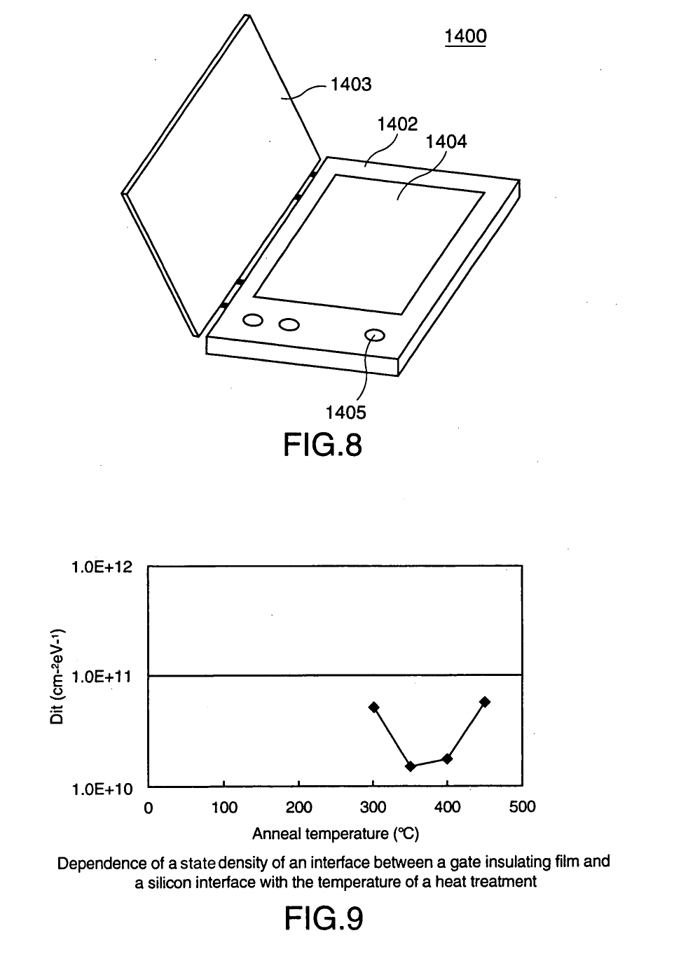

FIG. 8 is a schematic of an electronic book showing its structures as an example of electronic apparatus of an exemplary aspect of the present invention. In the figure, reference number 1400 indicates the electric book. The electric book 1400 has a book shaped frame 1402 and an openable and closable cover 1403 for the frame 1402. In the frame 1402, a display device 1404 is installed so as to expose its display surface and an operating portion 1405 is also installed. A controller, a counter, a memory and the like are installed inside the frame 1402. In this exemplary embodiment, the display device 1404 has a pixel part that is formed by filling electric ink into a thin film element, and a peripheral circuit that is integrated and provided together with the pixel part. The peripheral circuit includes a decoding type scan driver and a data driver.

The electronic apparatus and the information-processing device may include an electronic paper, a liquid crystal television, a view finder type or direct view type video tape recorder, a car navigation device, a pager, an electronic databook, a calculator, a word processor, a work station, a videophone, a point-of-sale terminal, equipments having a touch panel and the like, in addition to the personal computer in FIG. 5, the digital still camera in FIG. 7 and the electronic book in FIG. 8. The above-mentioned display device can be applied to the display parts of these pieces of electronic apparatus.

As explained above, according to the methods of manufacturing a transistor of the exemplary embodiments, processes, which are after the formation of the backup film and the heat treatment and through the final product, are performed with a temperature not exceeding 350° C. Therefore, high performance transistors can be stably provided and fine final products can be manufactured at a high yield rate.

Further, according to an aspect of the present invention, the backup film can be used as a source electrode or a drain electrode. Therefore, it is not necessary to newly set up a process of forming a source electrode or a drain electrode and it enables to simplify the manufacturing processes.

First Practical Example

A test substrate may be provided according to the following. A silicon dioxide film that serves as a gate insulating film is deposited on a silicon substrate in a thickness of about 100 nm. Then, as a metal film, aluminum (Al) is deposited in a thickness of about 100 nm by sputtering and the test substrate is obtained. A heat treatment is performed to the test substrate. Then, the substrate is examined to look at a relationship between a temperature change and a state density of an interface between the gate insulating film and a silicon interface. The determination of the state density of the interface is conducted with a mercury probe by a capacity-voltage (C-V) measurement method, after the aluminum is removed by wet etching.

A dependence of the state density of the interface between the gate insulating film and the silicon interface with the temperature of the heat treatment is shown in FIG. 9. As shown in the figure, when the heat treatment is performed with a temperature 300-450° C., the state density of the interface (Dit) becomes less than 1.0×10¹¹. It indicates that a condition of the interface is fine.

Second Practical Example

A heat treatment is performed to the test substrate manufactured in the first practical example and on which the aluminum has been removed. Then, the substrate is examined to look the relationship between the temperature change and the state density of the interface between the gate insulating film and the silicon interface. The measurement method and others are the same as those of the first practical example.

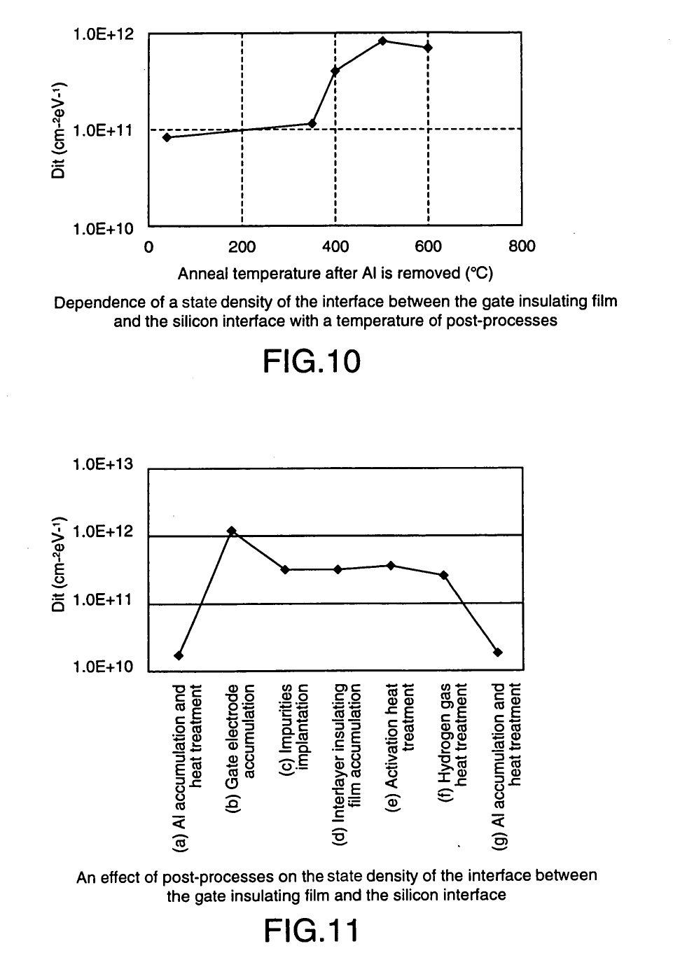

A dependence of the state density of the interface between the gate insulating film and the silicon interface with the temperature of the heat treatment after a treatment of aluminum is shown in FIG. 10. As shown in the figure, when the substrate is heated to a temperature more than 350° C. after a metal film is removed, the state density of the interface (Dit) rises rapidly. This may be attributed the fact that hydrogen, which is once bound to a dangling bond in the silicon film or at the film interface, is released by its thermal motion driven by the heat treatment using the aluminum layer, and the dangling bond is regenerated. From this fact, it should be understood that it is important to perform the rest of the processes within a temperature range that does not exceed 350° C. after the aluminum layer is removed.

Third Practical Example

A gate insulating film is formed on a silicon substrate and an aluminum layer is deposited. Then, a heat treatment is performed to the substrate and the aluminum layer is removed. And then, the substrate is exposed to a normal TFT manufacturing process. After this, the determination of the state density of the interface between the gate insulating film and the silicon interface in a case that the substrate is exposed to the normal TFT manufacturing process is conducted.

The manufacturing process is described below.

(a) A heat treatment with a temperature of 400° C. is performed to the test substrate manufactured in the same way as that of the first practical example for 30 minutes (Al deposition and heat treatment process).

(b) A gate wiring film is formed 500 nm thick by sputtering using tantalum after the aluminum layer is removed by etching. A temperature of a substrate heater at the time is 200° C. (gate wiring film forming process).

Then, the wiring film is patterned.

(c) A source-drain region and a channel region are formed by ion implantation into a silicon film. As a material gas for the ion implantation, phosphine (PH₃) is used (impurities implantation process).

(d) As an interlayer insulating film, an oxide silicon film is deposited 500 nm thick by parallel plate type PECVD using TEOS gas. A temperature of this film formation is 300° C. (interlayer insulating film accumulating process).

(e) In order to activate the implanted impurities of phosphorus, a heat treatment with a temperature of 300° C. is performed under a nitride atmosphere for 4 hours (activation heat treatment process).

(f) A heat treatment with a temperature of 300° C. is performed under a hydrogen atmosphere for 3 hours (hydrogen gas heat treatment process).

(g) Then, as a metal film, aluminum (Al) is deposited 500 nm thick by sputtering and a heat treatment is performed. A temperature of the heat treatment is 350° C. and time of the treatment is 60 minutes (Al deposition and heat treatment process).

The state density of the interface between the gate insulating film and the silicon interface is measured at each process (a) through (g).

A relationship between the state density of the interface between the gate insulating film and the silicon interface, and post-processes is shown in FIG. 11.

As shown in the figure, the state density of the interface is once dropped by the heat treatment after the aluminum is deposited. However, at the gate wiring film forming process right after this, the state density of the interface rises as a surface of the substrate reaches high temperature, and an interface defect increases again. Therefore, the Al deposition and heat treatment process may at least be performed after a process in which the surface of the substrate reaches high temperature.

Also, it should be understood from the figure that an interface enhancement effect can be obtained even when the Al deposition and the heat treatment process is performed after the interlayer insulating film is formed.

1. A method of manufacturing a transistor, comprising:
forming an interlayer film including a semiconductor film and at least two different films, the interlayer film having a dangling bond in the semiconductor film and/or at a vicinity of an interface of the semiconductor film;
forming a backup film that promotes a termination of the dangling bond over the interlayer film; and
performing a heat treatment after the backup film is formed, subsequent processes after the heat treatment being performed with a temperature lower than 350° C.

2. The method of manufacturing a transistor according to claim 1, further including forming a metal film or a semiconductor film as the backup film that promotes the termination of the dangling bond.

3. A method of manufacturing a transistor, comprising:
forming a semiconductor film on a substrate;
forming an insulating film on the semiconductor film;
forming a backup film made of a metal film or a semiconductor film over the insulating film; and
performing a heat treatment after the backup film is formed, subsequent processes after the heat treatment being performed with a temperature lower than 350° C.

4. The method of manufacturing a transistor according to claim 1, further including performing the heat treatment with a temperature of 300-450° C.

5. The method of manufacturing a transistor according to claim 2, the metal film or the semiconductor film being made of Al, Mg, Si, alloys of these elements or an interlayer film that includes a film made of any one of these elements or the alloys at the bottom.

6. The method of manufacturing a transistor according to claim 3, furthering including forming the transistor to have at least a source electrode, a drain electrode and a gate electrode, and forming the source electrode and/or the drain electrode when the metal film or the semiconductor film is formed.

7. The method of manufacturing a transistor according to claim 3, further including forming the transistor to have at least a source electrode, a drain electrode and a gate electrode, and forming a wiring layer over the source electrode and the drain electrode when the metal film or the semiconductor film is formed.

8. A circuit substrate, comprising:
the transistor obtained by the method according to claim 1.

9. An electro-optical device comprising:
the transistor obtained by the method according to claim 1.

10. An electronic apparatus comprising:
the transistor obtained by the method according to claim 1.
